(19) United States
(12) Patent Application Publication
(10) Pub. No.: US 2025/0309840 A1
(43) Pub. Date: Oct. 2, 2025

(54) POWER AMPLIFIER CASCODE BIAS GENERATION USING OUTPUT BIAS VOLTAGE

(71) Applicant: TEXAS INSTRUMENTS INCORPORATED, Dallas, TX (US)

(72) Inventor: Rohit Chatterjee, Bangalore (IN)

(21) Appl. No.: 18/619,618

(22) Filed: Mar. 28, 2024

(51) Int. Cl. H03F 3/24

(52) U.S. Cl. CPC H03F 3/245; H03F 2200/09; H03F 2200/129; H03F 2200/451

(57) ABSTRACT

Embodiments disclosed herein relate to power amplifiers and topology design thereof. In an example, a circuit includes a power amplifier (PA), a voltage divider, and a bias voltage generator circuit. The PA includes a first transistor coupled to receive a first input signal, a second transistor coupled to receive a second input signal, a third transistor coupled to the first transistor and coupled to the bias voltage generator circuit, and a fourth transistor coupled to the second transistor, the bias voltage generator circuit, and the third transistor. The voltage divider includes a first resistor and a second resistor. The first resistor is coupled to the third transistor of the PA. The second resistor is coupled to the fourth transistor of the PA. The first resistor and the second resistor are coupled to each other and coupled to the bias voltage generator circuit.

### TECHNICAL FIELD

This relates generally to power amplifiers, and more particularly, to generating bias voltages from power amplifiers.

### BACKGROUND

Radio frequency (RF) circuits are often used in electronic systems for communications applications. RF circuits can receive and transmit radio signals at varying frequencies and with varying gain based on their design. In order to receive and transmit RF signals, RF circuits often include a matching network, or balun, to perform impedance transformation and matching.

In some RF circuit designs, a transmitter circuit includes a power amplifier and an on-board matching network to provide maximum power transfer and impedance matching capabilities. In such designs, a supply voltage for biasing the power amplifier is provided by connecting this voltage to a suitable node in the on-board matching network. In these designs, the same supply voltage is also made accessible through a dedicated pin of the power amplifier chip to generate a cascode bias voltage for enabling such functionality. The cascode bias voltage may be supplied to sets of cascode transistors in a power amplifier to improve isolation, gain, and other performance of the power amplifier.

In other RF circuit designs, a transmitter circuit includes a power amplifier with an internal (i.e., on-chip) matching network. In these designs, the supply voltage for biasing the power amplifier can be connected to a center tap node of the matching network, and this center tap node can also be used to generate the cascode bias voltage. However, in these designs, a dedicated pin may still be required to connect the power amplifier supply power and the on-chip matching network. Regardless of implementation, the use of a dedicated pin for producing cascode bias voltages increases not only the cost and number of on-board components of a system, but also reduces the flexibility of the system for use by other elements of the system as an additional pin may be dedicated to such use.

### SUMMARY

Various embodiments disclosed herein relate to power amplifiers, and more particularly, to using a voltage divider coupled to a power amplifier to generate an output bias voltage from the power amplifier. In an example, a circuit is provided. The circuit includes a power amplifier, a voltage divider coupled to the power amplifier, and a bias voltage generator circuit coupled to the voltage divider and to the power amplifier. The power amplifier includes a first transistor including a gate terminal coupled to receive a first input signal, a second transistor including a gate terminal coupled to receive a second input signal, a third transistor coupled to the first transistor and coupled to the bias voltage generator circuit, and a fourth transistor coupled to the second transistor, the bias voltage generator circuit, and the third transistor. The voltage divider includes a first resistor that includes a first terminal and a second terminal and a second resistor that includes a first terminal and a second terminal. The first terminal of the first resistor is coupled to the third transistor of the power amplifier. The second terminal of the second resistor is coupled to the fourth transistor of the power amplifier. The second terminal of the first resistor and the first terminal of the second resistor are coupled to each other and coupled to the bias voltage generator circuit.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example system capable of producing a cascode bias voltage in an implementation.

FIG. 2 illustrates an example circuit capable of producing a cascode bias voltage in an implementation.

FIG. 3 illustrates example graphical representations of results produced by a circuit in an implementation.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Discussed herein are enhanced components, techniques, and systems related to radio frequency (RF) circuits, and more particularly, to generating output bias voltages using a voltage divider coupled to differential outputs of a power amplifier of an RF circuit. RF circuits are designed to receive and transmit radio signals at varying frequencies and with variable gain. In transmitters, specifically, a power amplifier may be included to increase power transfer between elements of an RF circuit and to transmit the RF signal to the antenna without significant insertion loss, noise, or other issues.

In embedded systems, such as systems-on-chip (SoCs), various elements of a system may be coupled together using conductive features and through pins and/or ports of the elements. In such systems, to provide impedance matching functionality, existing transmitter circuit designs often include an on-board or on-chip impedance matching network, or balun, coupled to a power amplifier of the transmitter. The supply voltage of the power amplifier can be connected to the matching network to provide a voltage bias at the outputs of the power amplifier. However, in such designs, an additional pin of the power amplifier may be required to generate and supply the bias voltage to other elements of the SoC. This may not only reduce the number of available pins for other connections to the power amplifier but also increase the complexity of on-board routing and increase the number of required on-board components for filtering supply noise, providing isolation between different rails, etc. Such designs may also increase cost due to the need for additional components and pins.

Disclosed herein is a circuit that includes a power amplifier, a voltage divider, and a bias voltage generator circuit that, when coupled together, can eliminate the requirement for a pin to produce and supply a cascode bias voltage. The voltage divider may include a pair of on-chip resistors connected to differential output pins of the power amplifier. In this way, the bias voltage can be generated from a node of the voltage divider and supplied to other elements of a system without the use of a pin of the power amplifier. Advantageously, the disclosed circuit can perform impedance matching, cascode bias voltage generation, and other functions with simplified on-board routing, reduced numbers of on-board components, and additional available pins, which may improve flexibility in use and design of the circuit, among other benefits.

In an example, a circuit is provided. The circuit includes a power amplifier, a voltage divider coupled to the power amplifier, and a bias voltage generator circuit coupled to the voltage divider and to the power amplifier. The power amplifier includes a first transistor including a gate terminal coupled to receive a first input signal, a second transistor including a gate terminal coupled to receive a second input signal, a third transistor coupled to the first transistor and coupled to the bias voltage generator circuit, and a fourth transistor coupled to the second transistor, the bias voltage generator circuit, and the third transistor. The voltage divider includes a first resistor that includes a first terminal and a second terminal and a second resistor that includes a first terminal and a second terminal. The first terminal of the first resistor is coupled to the third transistor of the power amplifier. The second terminal of the second resistor is coupled to the fourth transistor of the power amplifier. The second terminal of the first resistor and the first terminal of the second resistor are coupled to each other and coupled to the bias voltage generator circuit.

In another example, a system including a first amplifier stage and a second amplifier stage coupled to the first amplifier stage is provided. The second amplifier stage includes a power amplifier, a voltage divider coupled to the power amplifier, and a bias voltage generator circuit coupled to the voltage divider and to the power amplifier. The power amplifier includes a first transistor including a gate terminal coupled to receive a first input signal from the first amplifier stage, a second transistor including a gate terminal coupled to receive a second input signal from the first amplifier stage, a third transistor coupled to the first transistor and coupled to the bias voltage generator circuit, and a fourth transistor coupled to the second transistor, the bias voltage generator circuit, and the third transistor. The voltage divider includes a first resistor that includes a first terminal and a second terminal and a second resistor that includes a first terminal and a second terminal. The first terminal of the first resistor is coupled to the third transistor of the power amplifier. The second terminal of the second resistor is coupled to the fourth transistor of the power amplifier. The second terminal of the first resistor and the first terminal of the second resistor are coupled to each other and coupled to the bias voltage generator circuit.

In yet another example, a system is provided. The circuit includes a power amplifier, a voltage divider coupled to the power amplifier, a bias voltage generator circuit coupled to the voltage divider and to the power amplifier, and a balun coupled to the power amplifier and to the voltage divider. The power amplifier includes a first transistor including a gate terminal coupled to receive a first input signal, a second transistor including a gate terminal coupled to receive a second input signal, a third transistor coupled to the first transistor and coupled to the bias voltage generator circuit, and a fourth transistor coupled to the second transistor, the bias voltage generator circuit, and the third transistor. The voltage divider includes a first resistor that includes a first terminal and a second terminal and a second resistor that includes a first terminal and a second terminal. The first terminal of the first resistor is coupled to the third transistor of the power amplifier. The second terminal of the second resistor is coupled to the fourth transistor of the power amplifier. The second terminal of the first resistor and the first terminal of the second resistor are coupled to each other and coupled to the bias voltage generator circuit.

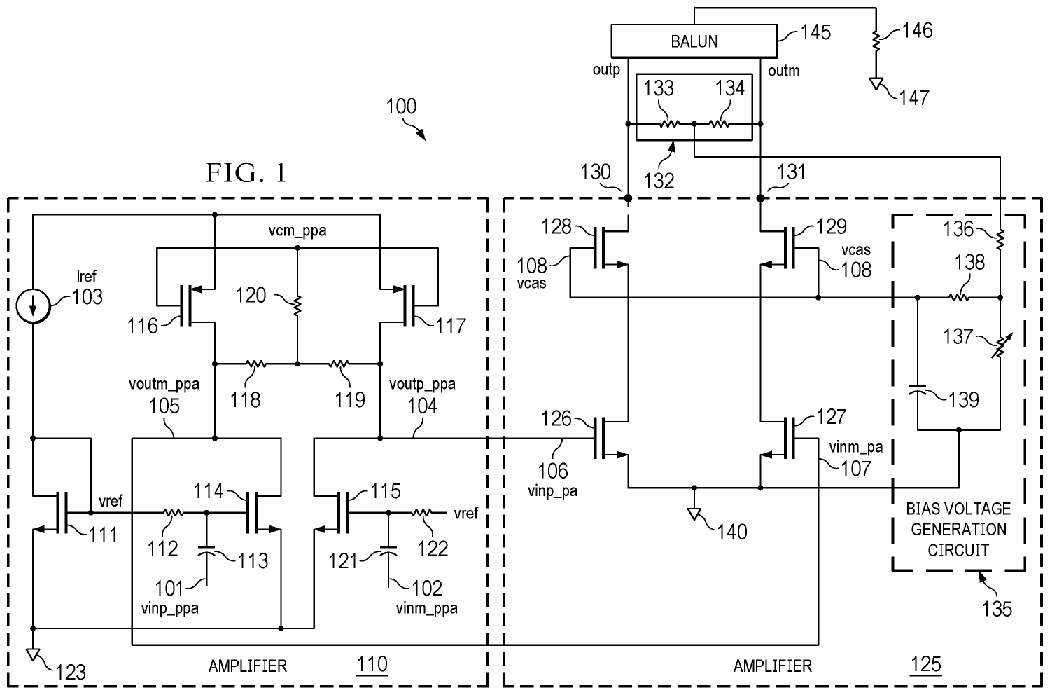

FIG. 1 illustrates an example system capable of producing a cascode bias voltage in an implementation. FIG. 1 shows system 100, which includes amplifier 110, amplifier 125, voltage divider 132, and balun 145. Amplifier 110 includes transistor 111, resistor 112, capacitor 113, transistor 114, transistor 115, transistor 116, transistor 117, resistor 118, resistor 119, resistor 120, capacitor 121, resistor 122, and ground node 123. Amplifier 125 includes transistor 126, transistor 127, transistor 128, transistor 129, bias voltage generation circuit 135, and ground node 140. Bias voltage generation circuit 135 includes resistor 136, resistor 137, resistor 138, and capacitor 139. Voltage divider 132 includes resistors 133 and 134. Each transistor of system 100 includes a gate, a drain, and a source, and each capacitor and resistor include a first terminal and a second terminal.

System 100 is representative of a circuit including a first amplifier stage (amplifier 110) and a second amplifier stage (amplifier 125) capable of providing power, gain, and impedance matching for elements of a device, such as a radio frequency (RF) device. System 100 includes amplifier 110 and amplifier 125 to perform such functions. In some examples, system 100 may be implemented on-board or as a system-on-chip (SoC). In some examples, some elements of system 100 may be implemented on-board and other elements may be off-board.

Amplifier 110 may be representative of a first amplifier stage coupled to receive input signals and coupled to provide output signals to amplifier 125. Examples of amplifier 110 include a pre-power amplifier, a mixer, or the like. Amplifier 110 may be coupled to receive an input power or input signals at first terminals of capacitors 113 and 121. More specifically, amplifier 110 may be coupled to receive input voltage 101 at a first terminal of capacitor 113 and input voltage 102 at a first terminal of capacitor 121. Input voltage 101 may be a positive signal, while input voltage 102 may be a negative signal. In other words, input voltages 101 and 102 may be differential input signals fed to amplifier 110. When inputs voltages 101 and 102 include non-zero signals, elements of amplifier 110 can produce output voltage 104, and output voltage 105 at different nodes within amplifier 110.

Capacitor 113, coupled to receive input voltage 101, includes a second terminal coupled to a first terminal of resistor 112 and coupled to a gate of transistor 114. Resistor 112 includes a second terminal coupled to a gate and a drain of transistor 111. Transistor 111 includes a gate, a drain, and a source. The drain of transistor 111 may also be coupled to the gate of transistor 111. The source of transistor 111 may be coupled to a source of transistor 114, a source of transistor 115, and ground node 123. In various examples, transistor 111 may be an n-type transistor, such as a n-type metal oxide semiconductor field effect transistor (MOSFET) (also referred to as an NMOS transistor).

Capacitor 121, coupled to receive input power 102, includes a second terminal coupled to a first terminal of resistor 122 and to a gate of transistor 115. The sources of transistors 114 and 115 may be coupled to each other and to ground node 123. The drain of transistor 114 may be coupled to a drain of transistor 116, and the drain of transistor 115 may be coupled to a drain of transistor 117. The drains of transistors 114 and 116 may also be coupled to a first terminal of resistor 118. The drains of transistors 115 and 117 may also be coupled to a first terminal of resistor 119. The second terminals of resistors 118 and 119 may be coupled together and may also be coupled to a first terminal of resistor 120. In other words, resistors 118 and 119 may be coupled together in series, and resistor 120 may be coupled in a star topology with respect to resistors 118 and 119. The second terminal of resistor 120 may be coupled to the gates of transistors 116 and 117. The sources of transistors 116 and 117 may be coupled together and may be coupled to the drain of transistor 111. In various examples, transistors 114 and 115 may be NMOS transistors, and transistors 116 and 117 may be p-type transistors, such as p-type MOSFETs (also referred to as PMOS transistors).

Amplifier 125, representative of a power amplifier, may be coupled to amplifier 110 at a first node between the drains of transistors 115 and 117 and at a second node between the drains of transistors 114 and 116. More specifically, a gate of transistor 126 may be coupled to the drains of transistors 115 and 117, and a gate of transistor 127 may be coupled to the drains of transistors 114 and 116. A voltage or signal at the first node may be referred to as output voltage 104 of amplifier 110 or as input voltage 106 of amplifier 125. A voltage or signal at the second node may be referred to as output voltage 105 of amplifier 110 or as input voltage 107 of amplifier 125. It follows that output voltages 104 and 105, or input voltages 106 and 107, may be differential signals applied to inputs of amplifier 125. When such signals include non-zero signals, amplifier 125 may function as a power amplifier capable of providing a gain and providing impedance matching functionality for system 100.

Transistors 126 and 127 may function as input nodes of amplifier 125. The sources of transistors 126 and 127 may be coupled together and to ground node 140. The drain of transistor 126 may be coupled to a source of transistor 128. The drain of transistor 127 may be coupled to a source of transistor 129. Transistors 128 and 129 may be representative of a first set of cascode transistors of amplifier 125. The gates of transistors 128 and 129 may be coupled together and may be coupled to receive cascode bias voltage 108 from bias voltage generation circuit 135. In various examples, transistors 126, 127, 128, and 129 may be NMOS transistors. In some examples, additional sets of cascode transistors may be included in amplifier 125. For example, a fifth transistor may be included between transistors 126 and 128, or more specifically, having a source coupled to the drain of transistor 126 and a drain coupled to the source of transistor 128, and a sixth transistor may be included between transistors 127 and 129, or more specifically, having a source coupled to the drain of transistor 127 and a drain coupled to the source of transistor 129. In such examples, a second bias voltage generation circuit may be coupled to provide a second cascode bias voltage to the gates of the fifth and sixth transistors.

Bias voltage generation circuit 135 includes resistor 136, resistor 137, resistor 138, and capacitor 139 and may be representative of a circuit capable of biasing an output voltage obtained from amplifier 125 and producing cascode bias voltage 108 to bias the set of cascode transistors of amplifier 125 (transistors 128 and 129). In some embodiments, additional bias voltage generation circuits may be included based on the number of sets of cascode transistors of amplifier 125.

Resistors 136 and 137 of bias voltage generation circuit 135 may form a programmable resistor array including a number of resistors coupled together in series with each other. In some examples, one or more of the resistors may be a variable resistor, such as resistor 137. Resistor 138 and capacitor 139 of bias voltage generation circuit 135 may form a resistor-capacitor (RC) circuit. As illustrated in FIG. 1, a first terminal of resistor 136 may be coupled to the second terminal of resistor 137 and to a first terminal of resistor 138. The first terminal of resistor 138 may also be coupled to the second terminal of resistor 137. The second terminal of resistor 138 may be coupled to the second terminal of capacitor 139, and the second terminals of resistor 138 and capacitor 139 may be coupled to the gates of transistors 128 and 129 to provide cascode bias voltage 108 to transistors 128 and 129.

The drains of transistors 128 and 129 may function as output nodes of amplifier 125. The output nodes of amplifier 125, output nodes 130 and 131, may be coupled to both voltage divider 132 and to balun 145. Voltage divider 132 includes resistors 133 and 134 that are coupled to each other in series. In some examples, resistors 133 and 134 may have the same resistance value (e.g., 2 kΩ). A first terminal of resistor 133 of voltage divider 132 may be coupled to the drain of transistor 128 (i.e., a first output node (output node 130)), and a first terminal of resistor 134 of voltage divider 132 may be coupled to the drain of transistor 129 (i.e., a second output node (output node 131)). The second terminals of resistors 133 and 134 may be coupled together and may be coupled to bias voltage generation circuit 135. In particular, the second terminals of resistors 133 and 134 may be coupled to the second terminal of resistor 136 of bias voltage generation circuit 135. In examples including multiple sets of cascode transistors, and thus multiple bias voltage generation circuits, amplifier 125 may also include a number of additional voltage dividers based on the number of sets of cascode transistors and bias voltage generation circuits. In such examples, each voltage divider may be coupled to an individual bias voltage generation circuit to provide a respective cascode bias voltage.

Balun 145 may be representative of an impedance matching network capable of receiving output signals from amplifier 125 and matching the impedance of the output signals for further use downstream, such as by an antenna or another element of an RF system. Balun 145 includes two inputs. A first input may be coupled to output node 130, or to the drain of transistor 128, and a second input may be coupled to output node 131, or to the drain of transistor 129. Balun 145 may also include an output coupled to a first terminal of resistor 146. The second terminal of resistor 146 can be coupled to ground node 147 and can be included to match the impedance of an antenna.

In operation, amplifier 125, as arranged, described, and shown in FIG. 1, can produce differential output voltages based on input voltages 106 and 107 and can generate cascode bias voltage 108 by using a voltage at a node of voltage divider 132 coupled to the output nodes of amplifier 125 based on the output voltages. In this way, amplifier 125, which may include a number of pins to connect to other elements of system 100, might not have a dedicated pin for generating and supplying the cascode bias voltages to sets of cascode transistors. Rather, the cascode transistors may be coupled to receive the cascode bias voltage 108 via internal connections and nodes within amplifier 125 and voltage divider 132. Advantageously, amplifier 125 may include fewer on-board components and pins relative to existing solutions that generate cascode bias voltages using a pin coupled to a supply pin of a power amplifier. Thus, both cost and design complexity may be reduced using the topology of amplifier 125.

In some examples, system 100 may include fewer, additional, or different elements. More particularly, amplifier 110 and/or amplifier 125 may include fewer, additional, or different elements. For example, amplifier 125 may include additional or fewer sets of cascode bias transistors. Similarly, in some examples, bias voltage generation circuit 135 may include fewer or additional elements. For example, bias voltage generation circuit 135 may include additional resistors as part of a programmable resistor array to influence bias voltages output by bias voltage generation circuit 135.

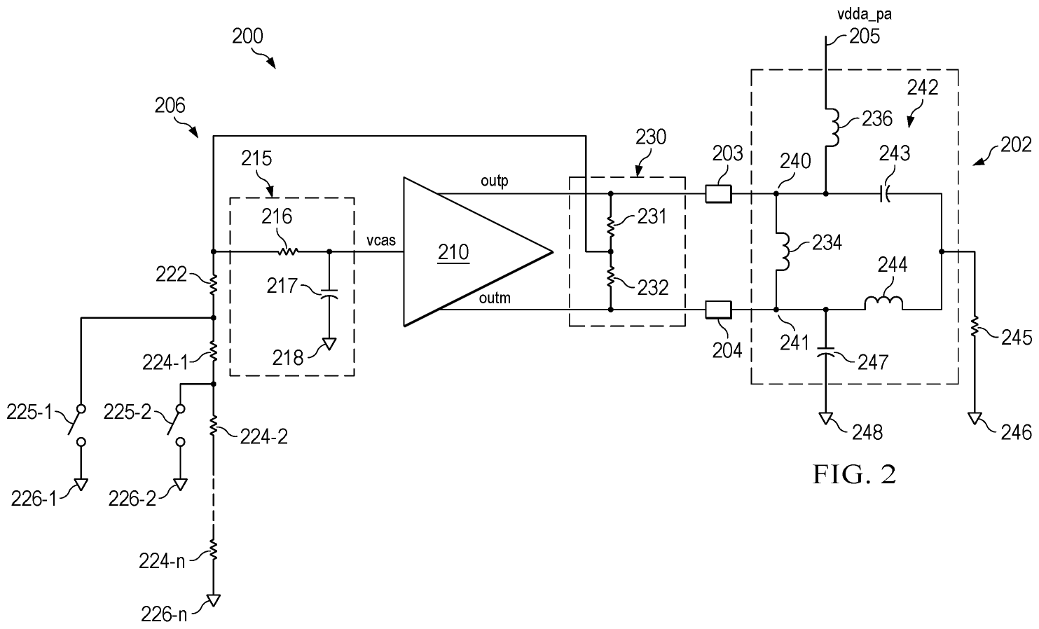

FIG. 2 illustrates an example circuit capable of producing a cascode bias voltage in an implementation. FIG. 2 shows circuit 200, which includes power amplifier 210, resistor-capacitor (RC) circuit 215, voltage divider 230, balun 242, and various resistors, switches, inductors, and other electrical components. RC circuit 215 includes resistor 216 and capacitor 217. Voltage divider 230 includes resistor 231 and resistor 232. Balun 242 includes inductor 234, inductor 236, capacitor 243, inductor 244, and capacitor 247.

In various examples, power amplifier 210 may be representative of and include one or more elements of amplifier 125 of FIG. 1. As such, power amplifier 210 may be configured to receive input signals, increase values of the input signals, and output signals based on the input signals for use by downstream systems or circuits. Power amplifier 210, and other elements of circuit 200, may be included on-board or as part of a system-on-chip. In such designs, power amplifier 210 may include various pins or ports (e.g., pin 203, pin 204) to connect to other elements of a system. For example, power amplifier 210 may include a connection to receive a supply voltage (e.g., voltage source 202) and one or more other pins 203 and 204 to provide output voltages 240 and 241, respectively, to balun 242 or downstream to other components.

Power amplifier 210 may include one or more inputs coupled to receive input signals. RC circuit 215 is coupled to power amplifier 210 at an input of power amplifier 210. More specifically, resistor 216 and capacitor 217 are coupled to the input of power amplifier 210. Resistor 216 and capacitor 217 each include two terminals. A first terminal of resistor 216 is coupled to a first terminal of capacitor 217, which are both coupled to power amplifier 210. The second terminal of capacitor 217 is coupled to ground node 218. The second terminal of resistor 216 is coupled to a first terminal of resistor 222.

Resistors 222, 224-1, 224-2, and 224-n are included in circuit 200 to form a programmable resistor array coupled to RC circuit 215 and to voltage divider 230 to produce cascode bias voltage 206. The resistor array may include any number of resistors, switches, and ground nodes based on a desired value for cascode bias voltage 206. Some resistors of the resistor array may be connected to circuit 200 or disconnected from circuit 200 (i.e., connected to one of ground nodes 226) via switches 225. Resistor 222 includes a first terminal coupled to RC circuit 215 and to voltage divider 230 and a second terminal coupled to a first terminal of resistor 224-1 and to switch 225-1. Switch 225-1 may be coupled to ground node 226-1 when closed. Resistor 224-1 includes a second terminal coupled to switch 225-2 and coupled to a first terminal of resistor 224-2. Switch 225-2 may be coupled to ground node 226-2 when closed. Resistor 224-2 includes a second terminal coupled to a first terminal of resistor 224-n, and resistor 224-n includes a second terminal coupled to ground node 226-n.

Voltage divider 230 includes resistors 231 and 232 and is coupled to output nodes of power amplifier 210, to the resistor array, and to RC circuit 215. Resistor 231 includes a first terminal coupled to a first output node of power amplifier 210 and a second terminal coupled to a first terminal of resistor 232. Resistor 232 includes a second terminal coupled to a second output node of power amplifier 210. The second terminal of resistor 231 and the first terminal of resistor 232 are coupled to the resistor array and to RC circuit 215. This node between the second terminal of resistor 231 and the first terminal of resistor 232 may be a low swing node, suitable for connecting to the resistor network and to RC circuit 215 for the generation of cascode bias voltage 206. In this way, voltage divider 230 may be included in circuit 200 to provide an internal node for the generation of cascode bias voltage 206 without the need of an additional pin. Thus, circuit 200 may generate supply voltage 205 from a node of voltage divider 230, and might not, such as in other examples, include additional components and/or pins for such use. For example, in existing solutions, circuit 200 may include a resistor and a pin coupled to both RC circuit 215 and to resistor 222 as opposed to including voltage divider 230, among other components. In such examples, the additional resistor may couple to a pin of power amplifier 210 to generate the cascode bias voltage. However, these solutions require increased components and wiring relative to the design of circuit 200.

Voltage divider 230 may further be coupled to pin 203, pin 204, which may be coupled to elements of balun 242. More specifically, the first terminal of resistor 231 may be coupled to pin 203. The second terminal of resistor 232 may be coupled to pin 204.

Amplifier 210 may provide output voltages 240 and 241 at pins 203 and 204, respectively. In various examples, amplifier 210 may further be coupled to balun 242 via pins 203 and 204 for impedance matching of output voltages 240 and 241. More specifically, balun 242 may include inductor 234, inductor 236, capacitor 243, inductor 244, and capacitor 247, which each include first and second terminals. The first terminal of inductor 234 may be coupled to pin 203, to the first terminal of capacitor 243, and to the first terminal of inductor 236. The second terminal of inductor 236 may be coupled to voltage source 202 of circuit 200. The second terminal of inductor 234 may be coupled to pin 204, to the first terminal of inductor 244, and to the first terminal of capacitor 247. The second terminal of capacitor 247 may be coupled to ground node 248. The first terminal of capacitor 243 may be coupled to pin 203, and the first terminal of inductor 244 may be coupled to pin 204. The second terminals of capacitor 243 and inductor 244 may be coupled together and may be further coupled to a first terminal of resistor 245, which represents an antenna impedance (e.g., 50 ohms). The second terminal of resistor 245 may be coupled to ground node 246. In some examples, balun 242 may be on the same board as circuit 200. In some examples, balun 242 may be off-board relative to circuit 200.

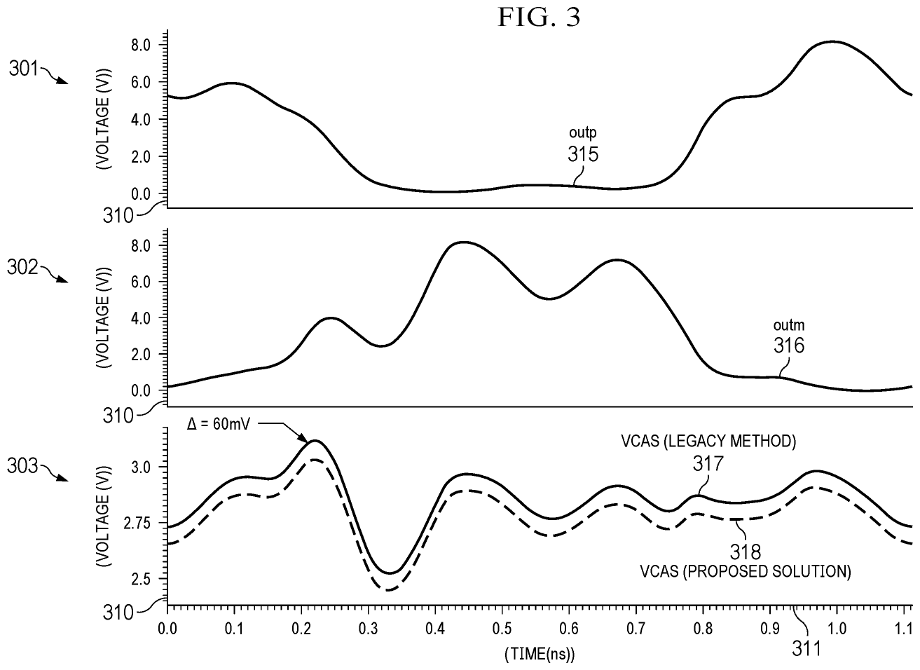

FIG. 3 illustrates example graphical representations of results produced by a circuit in an implementation. FIG. 3 shows graphical representations 301, 302, and 303, each with respect to voltage 310 and time 311. Graphical representation 301 includes waveform 315, graphical representation 302 includes waveform 316, and graphical representation 303 includes waveforms 317 and 318. The results demonstrated by the waveforms in graphical representations 301, 302, and 303 may be produced at nodes of a system including a power amplifier, a voltage divider, and a bias voltage generation circuit, such as system 100 of FIG. 1 or circuit 200 of FIG. 2.

Waveform 315 of graphical representation 301 may reflect sample results of a first output signal of a power amplifier, such as output voltage 240 of power amplifier 210 of FIG. 2. In some examples, this output voltage may be a positive differential signal. Similarly, waveform 316 of graphical representation 302 may reflect sample results of a second output signal of the power amplifier, such as output voltage 240 of power amplifier 210 of FIG. 2. In such examples, this output voltage may be a negative differential signal.

Waveform 317 of graphical representation 303 may reflect sample results of a cascode bias voltage, such as cascode bias voltage 206 of FIG. 2 or cascode bias voltage 108 of FIG. 1, produced by a circuit including a power amplifier, an RC circuit, and a resistor network. More specifically, waveform 317 may represent a cascode bias voltage produced by such a circuit when a dedicated pin of the power amplifier is used to generate the cascode bias voltage from a supply power of the power amplifier. For example, waveform 317 may include results of a cascode bias voltage produced at the first terminal of a resistor of a previous power amplifier solution that includes the resistor and an additional pin and that does not include voltage divider 230 as in circuit 200.

Waveform 318 of graphical representation 303 may reflect sample results of a cascode bias voltage produced by a circuit including power amplifier, voltage divider, RC circuit, and resistor array. More specifically, waveform 318 may represent a cascode bias voltage produced by such a circuit from a node between resistors of the voltage divider that is coupled to the RC circuit, the resistor array, and an input of the power amplifier. For example, waveform 318 may include results of cascode bias voltage 206 of circuit 200 in designs where circuit 200 includes voltage divider 230 and does not include an additional resistor and pin to generate cascode bias voltage 206.

As illustrated in graphical representation 303, the difference between the values of waveform 317 and waveform 318 may be approximately 60 mV. In other words, the voltage 310 of the cascode bias voltage of waveform 317 may be approximately 60 mV higher than the voltage 310 of the cascode bias voltage of waveform 318. Accordingly, while design topology may differ between a circuit or system that produces waveform 317 and a circuit or system that produces waveform 318, such as the number of pins used to generate the cascode bias voltage, the ripple magnitude may be approximately the same. In fact, the results indicate that the design topology differences do not impact the output power and power amplifier performance of the power amplifier of the circuit or system.

While some examples provided herein are described in the context of an embedded system, a system-on-chip, an integrated circuit, sub-circuit, component, device, element, topology, architecture, or environment, the systems, circuits, and methods described herein are not limited to such embodiments and may apply to a variety of other processes, systems, applications, devices, and the like.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or elements are presented in a given order, alternative implementations may perform routines having steps, or employ systems having elements or components, in a different order, and some processes or elements may be deleted, moved, added, subdivided, combined, and/or modified to provide alternative or subcombinations. Each of these processes or elements may be implemented in a variety of different ways. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A circuit, comprising:
a power amplifier;
a voltage divider coupled to the power amplifier; and
a bias voltage generator circuit coupled to the voltage divider and to the power amplifier;
wherein the power amplifier comprises:
a first transistor including a gate terminal coupled to receive a first input signal;
a second transistor including a gate terminal coupled to receive a second input signal;
a third transistor coupled to the first transistor and coupled to the bias voltage generator circuit; and
a fourth transistor coupled to the second transistor, the bias voltage generator circuit, and the third transistor; and
wherein the voltage divider comprises:
a first resistor that includes a first terminal and a second terminal; and
a second resistor that includes a first terminal and a second terminal;
wherein the first terminal of the first resistor is coupled to the third transistor of the power amplifier;
wherein the second terminal of the second resistor is coupled to the fourth transistor of the power amplifier; and
wherein the second terminal of the first resistor and the first terminal of the second resistor are coupled to each other and coupled to the bias voltage generator circuit.

2. The circuit of claim 1, wherein:
the first transistor further includes a source terminal and a drain terminal;
the second transistor further includes a source terminal and a drain terminal;
the third transistor includes a gate terminal, a source terminal, and a drain terminal;
the fourth transistor includes a gate terminal, a source terminal, and a drain terminal;
wherein the first terminal of the first resistor and the drain terminal of the third transistor are coupled to a balun; and
wherein the second terminal of the second resistor and the drain terminal of the fourth transistor are coupled to the balun.

3. The circuit of claim 2, wherein:
the source terminals of the first transistor and the second transistor are coupled to a ground node and are coupled to the bias voltage generator circuit;
the drain terminal of the first transistor is coupled to the source terminal of the third transistor; and
the drain terminal of the second transistor is coupled to the source terminal of the fourth transistor.

4. The circuit of claim 3, wherein the bias voltage generator circuit comprises:
a third resistor that includes a first terminal and a second terminal;
a fourth resistor that includes a first terminal and a second terminal;
a fifth resistor that includes a first terminal and a second terminal; and
a capacitor that includes a first terminal and a second terminal;
wherein the first terminal of the third resistor is coupled to the second terminal of the first resistor and the first terminal of the second resistor of the voltage divider;
wherein the second terminal of the third resistor is coupled to the first terminal of the fourth resistor and the first terminal of the fifth resistor;
wherein the second terminal of the fourth resistor is coupled to the first terminal of the capacitor and to the gate terminals of the third transistor and the fourth transistor; and
wherein the second terminal of the capacitor and the second terminal of the fifth resistor are coupled together, are coupled to the ground node, and are coupled to the source terminals of the first transistor and the second transistor.

5. The circuit of claim 1, wherein the power amplifier further comprises:
a fifth transistor that includes a gate terminal, a source terminal, and a drain terminal; and
a sixth transistor that includes a gate terminal, a source terminal, and a drain terminal;
wherein the source terminal of the fifth transistor is coupled to the drain terminal of the first transistor;
wherein the gate terminal of the fifth transistor is coupled to the gate terminal of the sixth transistor and to a second bias voltage generator circuit;
wherein the drain terminal of the fifth transistor is coupled to the source terminal of the third transistor;
wherein the source terminal of the sixth transistor is coupled to the drain terminal of the second transistor; and
wherein the drain terminal of the sixth transistor is coupled to the source terminal of the fourth transistor.

6. The circuit of claim 5, wherein the first, second, third, fourth, fifth, and sixth transistors comprise n-type transistors.

7. The circuit of claim 1, further comprising an input amplifier that includes a first node coupled to provide the first input signal to the first transistor and a second node coupled to provide the second input signal to the second transistor.

8. The circuit of claim 7, wherein the input amplifier is one of a power amplifier driver, a pre-power amplifier, and a mixer.

9. The circuit of claim 7, wherein the first input signal and second input signal are differential signals.

10. A system, comprising:
a first amplifier stage; and
a second amplifier stage coupled to the first amplifier stage;
wherein the second amplifier stage comprises:
a power amplifier;
a voltage divider coupled to the power amplifier; and
a bias voltage generator circuit coupled to the voltage divider and to the power amplifier;
wherein the power amplifier comprises:
a first transistor including a gate terminal coupled to receive a first input signal from the first amplifier stage;
a second transistor including a gate terminal coupled to receive a second input signal from the first amplifier stage;
a third transistor coupled to the first transistor and coupled to the bias voltage generator circuit; and
a fourth transistor coupled to the second transistor, the bias voltage generator circuit, and the third transistor; and
wherein the voltage divider comprises:
a first resistor that includes a first terminal and a second terminal; and
a second resistor that includes a first terminal and a second terminal;
wherein the first terminal of the first resistor is coupled to the third transistor of the power amplifier;
wherein the second terminal of the second resistor is coupled to the fourth transistor of the power amplifier; and
wherein the second terminal of the first resistor and the first terminal of the second resistor are coupled to each other and coupled to the bias voltage generator circuit.

11. The system of claim 10, wherein:
the first transistor further includes a source terminal and a drain terminal;
the second transistor further includes a source terminal and a drain terminal;
the third transistor includes a gate terminal, a source terminal, and a drain terminal; and
the fourth transistor includes a gate terminal, a source terminal, and a drain terminal;
wherein the first terminal of the first resistor and the drain terminal of the third transistor are coupled to a balun; and
wherein the second terminal of the second resistor and the drain terminal of the fourth transistor are coupled to the balun.

12. The system of claim 11, wherein:
the source terminals of the first transistor and the second transistor are coupled to a ground node and are coupled to the bias voltage generator circuit;
the drain terminal of the first transistor is coupled to the source terminal of the third transistor; and
the drain terminal of the second transistor is coupled to the source terminal of the fourth transistor.

13. The system of claim 12, wherein the bias voltage generator circuit comprises:
a third resistor that includes a first terminal and a second terminal;
a fourth resistor that includes a first terminal and a second terminal;
a fifth resistor that includes a first terminal and a second terminal; and
a capacitor that includes a first terminal and a second terminal;
wherein the first terminal of the third resistor is coupled to the second terminal of the first resistor and the first terminal of the second resistor of the voltage divider;
wherein the second terminal of the third resistor is coupled to the first terminal of the fourth resistor and the first terminal of the fifth resistor;
wherein the second terminal of the fourth resistor is coupled to the first terminal of the capacitor and to the gate terminal of the third transistor and the fourth transistor; and
wherein the second terminal of the capacitor and the second terminal of the fifth resistor are coupled together, are coupled to the ground node, and are coupled to the source terminals of the first transistor and the second transistor.

14. The system of claim 10, wherein the power amplifier further comprises:
a fifth transistor that includes a gate terminal, a source terminal, and a drain terminal; and
a sixth transistor that includes a gate terminal, a source terminal, and a drain terminal;
wherein the source terminal of the fifth transistor is coupled to the drain terminal of the first transistor;
wherein the gate terminal of the fifth transistor is coupled to the gate terminal of the sixth transistor and to a second bias voltage generator circuit;
wherein the drain terminal of the fifth transistor is coupled to the source terminal of the third transistor;
wherein the source terminal of the sixth transistor is coupled to the drain terminal of the second transistor; and
wherein the drain terminal of the sixth transistor is coupled to the source terminal of the fourth transistor.

15. The system of claim 10, wherein the first amplifier stage comprises one of a pre-power amplifier, a mixer, and a power amplifier driver.

16. A system, comprising:
a power amplifier;
a voltage divider coupled to the power amplifier;
a bias voltage generator circuit coupled to the voltage divider and to the power amplifier; and
a balun coupled to the power amplifier and to the voltage divider;
wherein the power amplifier comprises:
a first transistor including a gate terminal coupled to receive a first input signal;
a second transistor including a gate terminal coupled to receive a second input signal;
a third transistor coupled to the first transistor and coupled to the bias voltage generator circuit; and
a fourth transistor coupled to the second transistor, the bias voltage generator circuit, and the third transistor; and
wherein the voltage divider comprises:
a first resistor that includes a first terminal and a second terminal; and
a second resistor that includes a first terminal and a second terminal;
wherein the first terminal of the first resistor is coupled to the third transistor of the power amplifier;
wherein the second terminal of the second resistor is coupled to the fourth transistor of the power amplifier; and
wherein the second terminal of the first resistor and the first terminal of the second resistor are coupled to each other and coupled to the bias voltage generator circuit.

17. The system of claim 16, wherein:
the first transistor further includes a source terminal and a drain terminal;
the second transistor further includes a source terminal and a drain terminal;
the third transistor includes a gate terminal, a source terminal, and a drain terminal; and
the fourth transistor includes a gate terminal, a source terminal, and a drain terminal;
wherein the first terminal of the first resistor and the drain terminal of the third transistor are coupled to a balun; and
wherein the second terminal of the second resistor and the drain terminal of the fourth transistor are coupled to the balun.

18. The system of claim 17, wherein:
the source terminals of the first transistor and the second transistor are coupled to a ground node and are coupled to the bias voltage generator circuit;
the drain terminal of the first transistor is coupled to the source terminal of the third transistor; and
the drain terminal of the second transistor is coupled to the source terminal of the fourth transistor.

19. The system of claim 18, wherein the bias voltage generator circuit comprises:
a third resistor that includes a first terminal and a second terminal;
a fourth resistor that includes a first terminal and a second terminal;
a fifth resistor that includes a first terminal and a second terminal; and
a capacitor that includes a first terminal and a second terminal;
wherein the first terminal of the third resistor is coupled to the second terminal of the first resistor and the first terminal of the second resistor of the voltage divider;
wherein the second terminal of the third resistor is coupled to the first terminal of the fourth resistor and the first terminal of the fifth resistor;
wherein the second terminal of the fourth resistor is coupled to the first terminal of the capacitor and to the gate terminal of the fourth transistor; and
wherein the second terminal of the capacitor and the second terminal of the fifth resistor are coupled together, are coupled to the ground node, and are coupled to the source terminals of the first transistor and the second transistor.

20. The system of claim 15, wherein the power amplifier further comprises:
a fifth transistor that includes a gate terminal, a source terminal, and a drain terminal; and
a sixth transistor that includes a gate terminal, a source terminal, and a drain terminal;
wherein the source terminal of the fifth transistor is coupled to the drain terminal of the first transistor;
wherein the gate terminal of the fifth transistor is coupled to the gate terminal of the sixth transistor and to a second bias voltage generator circuit;
wherein the drain terminal of the fifth transistor is coupled to the source terminal of the third transistor;
wherein the source terminal of the sixth transistor is coupled to the drain terminal of the second transistor; and
wherein the drain terminal of the sixth transistor is coupled to the source terminal of the fourth transistor.
